(19) United States
(12) Patent Application Publication
(10) Pub. No.: US 2016/0274145 A1
(43) Pub. Date: Sep. 22, 2016

(54) Reconstruction Of Scanning Probe Microscopy Cantilever Tip

(71) Applicant: HGST Netherlands B.V., Amsterdam (NL)

(72) Inventors: Noreen Grace A. Borromeo, Cabuyao City (PH); Jessica Irish D. Lopez, Iligan City (PH); Jovy Anne V. Rato, Muntinlupa City (PH)

(21) Appl. No.: 14/662,208

(22) Filed: Mar. 18, 2015

(51) Int. Cl. G01Q 60/38; H01J 37/305

(52) U.S. Cl. CPC G01Q 60/38; H01J 37/3056; B81C 99/001

(57) ABSTRACT

A method for reconstructing a scanning probe microscopy (SPM) cantilever tip using focused ion beam (FIB) milling, such as reconstructing an atomic force microscopy (AFM) tip for reuse, involves mounting a used cantilever with tip and tip point on a FIB stub cantilever holder, thereby exposing the tip. A milling pattern is created on one or on both of a first side and a second side of the tip point, and the one or both sides of the tip point is/are FIB-milled according to the respective milling pattern, thereby creating a reconstructed tip for reuse rather than disposal.

### FIELD OF EMBODIMENTS

Embodiments of the invention may relate generally to scanning probe microscopy equipment and more particularly to reconstruction of a scanning probe microscopy cantilever tip to enable continued use.

### BACKGROUND

Atomic Force Microscopy (AFM) is a type of scanning probe microscopy that has very high resolution, demonstrated on the order of fractions of nanometers. The AFM consists of a cantilever with a sharp tip (probe) at its end that is used to scan the specimen surface. The AFM probe (commonly called AFM tip) is a consumable device with a sharp tip in the scale of micrometers and with a tip radius in the scale of nanometers. A good AFM tip should be sharp enough in order to get accurate and precise surface topography and measurement information. Once the AFM images are no longer suitably sharp, the AFM tip should be replaced.

In the context of hard disk drive read/write heads, AFM is usually used for surface topography and measurement of critical head parameters such as the magnetic write head pole tip and other features which are in nanometer and micrometer scales. The measurements needed to support these requirements should be as accurate as possible as they have an effect on the head performance. Therefore, AFM tips should be replaced as necessary to meet such requirements. On average, one AFM tip is replaced every 80-100 engages, which is equivalent to one to two days of typical use. As a common practice, used AFM tips are disposed as there is no known procedure on how to re-use or recycle them.

Any approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### SUMMARY OF EMBODIMENTS

Embodiments of the invention are directed toward a method for reconstructing a scanning probe microscopy (SPM) cantilever tip using focused ion beam (FIB) milling, such as reconstructing an atomic force microscopy (AFM) tip for reuse, and to a reconstructed SPM tip prepared by such a method. A used cantilever with tip is mounted on a FIB stub cantilever holder, thereby exposing first and second sides of the tip. A milling pattern is created on one or on both of the first side and the second side of the tip, and the one or both sides of the tip is/are FIB-milled according to the respective milling pattern, thereby creating a reconstructed tip.

According to embodiments, the cantilever and or the tip may be aligned at respective predetermined angles relative to a predetermined direction. Further, according to embodiments, the reconstructed tip may be plasma-cleaned to create a cleaned reconstructed tip, which may be exposed to an ionizer to neutralize the charge on the cleaned reconstructed tip.

Embodiments discussed in the Summary of Embodiments section are not meant to suggest, describe, or teach all the embodiments discussed herein. Thus, embodiments of the invention may contain additional or different features than those discussed in this section. Furthermore, no limitation, element, property, feature, advantage, attribute, or the like expressed in this section, which is not expressly recited in a claim, limits the scope of any claim in any way.

### BRIEF DESCRIPTION OF THE DRAWINGS

Embodiments are illustrated by way of example, and not by way of limitation, in the figures of the accompanying drawings and in which like reference numerals refer to similar elements and in which:

FIG. 1 is a flow diagram illustrating a method for reconstructing a scanning probe microscopy cantilever tip, according to an embodiment;

FIG. 2 is a side view illustrating a used scanning probe microscopy cantilever tip mounted on a focused ion beam (FIB) stub, according to an embodiment;

FIG. 3 illustrates an aligned cantilever, according to an embodiment;

FIG. 4 illustrates a microscopic image of an aligned tip, according to an embodiment;

FIG. 5A illustrates a microscopic image of a first FIB milling pattern, according to an embodiment;

FIG. 5B illustrates a microscopic image of a second FIB milling pattern, according to an embodiment;

FIG. 6A illustrates a microscopic image of a used scanning probe microscopy cantilever tip, according to an embodiment; and

FIG. 6B illustrates a microscopic image of a reconstructed used scanning probe microscopy cantilever tip, according to an embodiment.

### DETAILED DESCRIPTION

Approaches to a process for reconstructing a scanning probe microscopy tip are described. In the following description, for the purposes of explanation, numerous specific details are set forth in order to provide a thorough understanding of the embodiments of the invention described herein. It will be apparent, however, that the embodiments of the invention described herein may be practiced without these specific details. In other instances, well-known structures and devices are shown in block diagram form in order to avoid unnecessarily obscuring the embodiments of the invention described herein.

### INTRODUCTION

As mentioned, a good scanning probe microscopy (SPM) tip (e.g., an atomic force microscopy, or AFM, tip) should be sharp enough in order to get accurate and precise surface topography and measurement information. Once the AFM images are no longer suitably sharp, the AFM tip is typically replaced. In a hard disk drive manufacturing context, on average, one AFM tip is replaced every 80-100 engages, which is equivalent to one to two days of typical use. As a common practice, used AFM tips are disposed as there is no known procedure on how to re-use or recycle them.

Upon studying the condition of the AFM tips for disposal, almost 80% of them have the potential to be reconstructed. Given the available resources such as focused ion beam (FIB) machines, a procedure for reconstructing the AFM tip for re-use provides an opportunity to maximize the AFM tip's usability with potential for cost savings.

### A Method for Reconstructing a Scanning Probe Microscopy Cantilever Tip

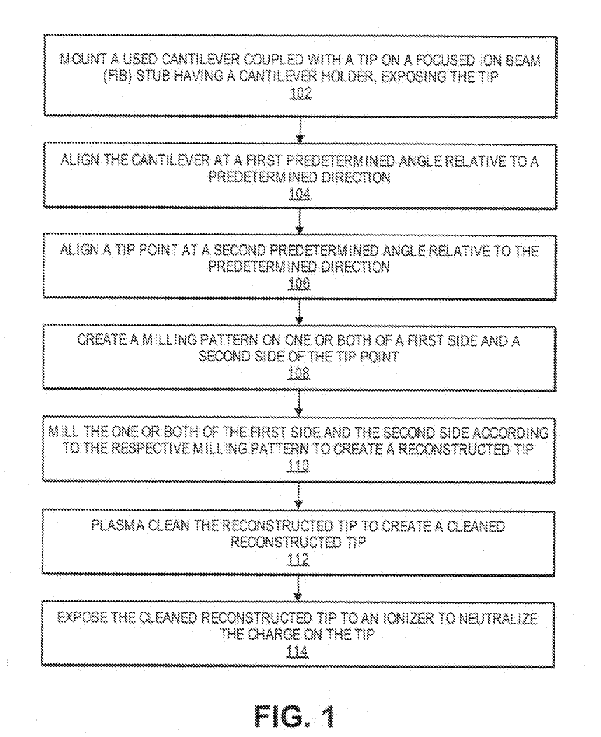

FIG. 1 is a flow diagram illustrating a method for reconstructing a scanning probe microscopy cantilever tip, according to an embodiment.

At block 102, a used cantilever coupled with a tip is mounted on a focused ion beam (FIB) stub having a cantilever holder, thereby exposing the tip.

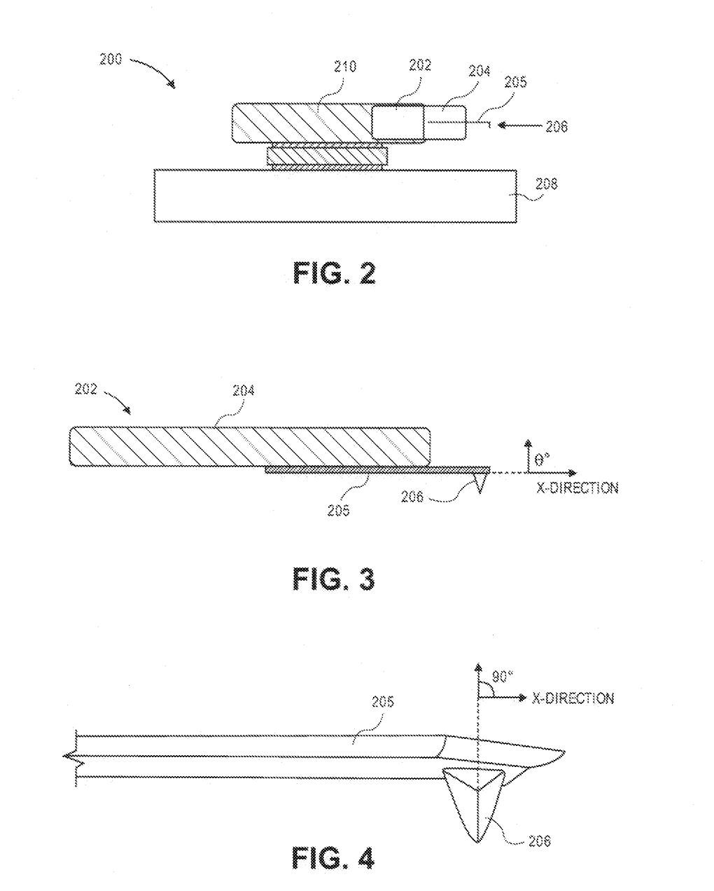

FIG. 2 is a side view illustrating a used scanning probe microscopy cantilever tip mounted on a focused ion beam (FIB) stub, according to an embodiment. Mount assembly 200 comprises a scanning probe microscopy (SPM) probe 202, disposed in a holder 210 which is attached to a FIB stub 208, where the probe 202 comprises a cantilever 204 having a tip 205 coupled therewith. The tip 205 comprises a tip point 206. FIB is a technique for analysis and ablation of a sample, and is embodied in a FIB instrument that uses a focused beam of ions to image a sample. FIB systems operate similarly to a scanning electron microscope (SEM) but using the beam of ions rather than a beam of electrons, where the beam of ions can be operated at low currents for imaging purposes and at higher currents for milling purposes, e.g., by sputtering atoms from the surface of the sample. Thus, FIB machines can be used to etch and/or machine surfaces, for purposes such as described herein.

According to an embodiment, the SPM probe 202 is an atomic force microscopy (AFM) type probe. AFM is a high-resolution type of SPM, demonstrating resolution on the scale of nanometers, e.g., for imaging and/or measuring. Generally, AFM procedures map the topography of a sample by mechanically interacting with the sample via a probe, such as probe 202. The tip point 206 is used to “feel” the surface of the sample, with the physical variations of the sample surface being transmitted by/through the tip 205 and cantilever 204, ultimately for processing according to whatever operation is being performed, e.g., imaging, measuring, etc.

Returning to FIG. 1, according to an embodiment, at block 104 the cantilever is aligned at a first predetermined angle relative to a predetermined direction. FIG. 3 illustrates an aligned cantilever, according to an embodiment. FIG. 3 depicts the probe 202 with the cantilever 204, e.g., as being held in the holder 210 (FIG. 2). According to an embodiment, the cantilever 204 is aligned at 0° in the x-direction. For example, cantilever 204 is aligned (e.g., using a 65× magnification view) horizontally using the XT alignment feature of the FIB, such as depicted in FIG. 3.

With reference to FIG. 1, according to an embodiment, at block 106 the tip point is aligned at a second predetermined angle relative to the predetermined direction. FIG. 4 illustrates a microscopic image of an aligned tip point, according to an embodiment. FIG. 4 depicts the tip 205 with the tip point 206 coupled therewith, e.g., as being held in the holder 210 (FIG. 2). According to an embodiment, the tip 206 is aligned at 90° to the x-direction, i.e., perpendicular to the x-axis. For example, tip 206 is aligned (e.g., using a 500× magnification view) using the XT alignment feature of the FIB, such as depicted in FIG. 4.

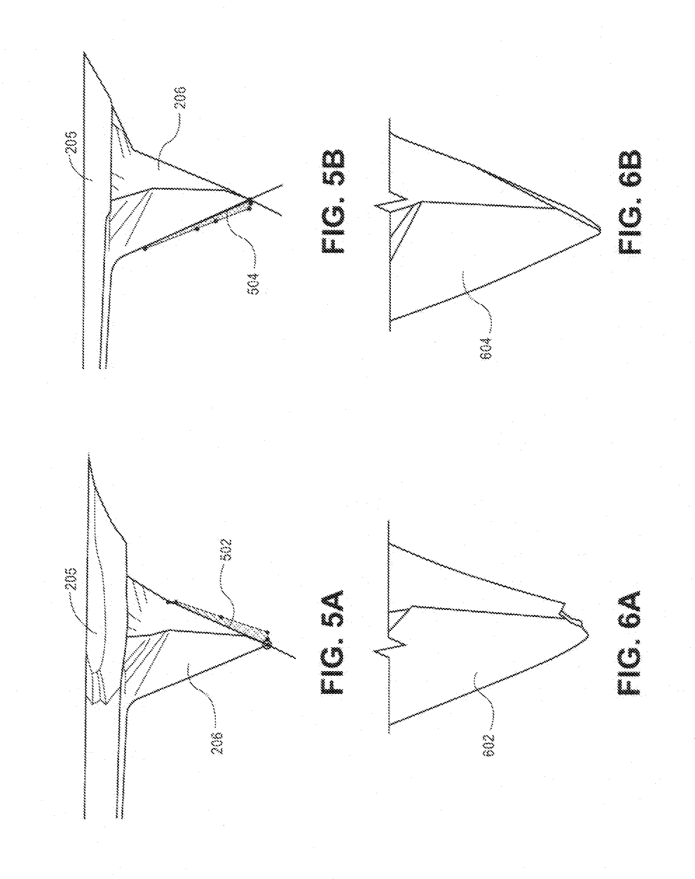

With continued reference to FIG. 1, at block 108 a milling pattern is created on one or on both of a first side and a second side of the tip point. FIG. 5A illustrates a microscopic image of a first FIB milling pattern, according to an embodiment. FIG. 5A illustrates a microscopic image as viewed through a FIB instrument, and showing the tip 205 and the tip point 206, with a first milling pattern 502 superimposed thereon. For a non-limiting example, the magnification may be set to 3500× at 0⁰ tilting to obtain a full view of the probe tip point 206 and, using the pattern window associated with the FIB instrument, the Line/Polygon is selected to create a milling pattern 502 to mill one side of the tip point 206.

Similarly, according to an embodiment, a second milling pattern is created on the second side of tip point 206. FIG. 5B illustrates a microscopic image of a second FIB milling pattern, according to an embodiment. FIG. 5B illustrates a microscopic image as viewed through a FIB instrument, and showing the tip 205 and the tip point 206, with a second milling pattern 504 superimposed thereon. For a non-limiting example, the magnification may be set to 3500× at 0⁰ tilting to obtain a full view of the probe tip point 206 and, using the pattern window associated with the FIB instrument, the Line/Polygon is selected to create a milling pattern 504 to mill the other side of the tip point 206. According to an embodiment, creating one or more milling pattern at block 108 includes creating a first milling line (e.g., milling pattern 502) on the first side of the tip point 206 and a second milling line (e.g., milling pattern 504) on the second side of the tip point 206. In a related embodiment, the first milling pattern 502 and the second milling pattern 504 are created so that the two milling lines intersect on the surface of the tip point 206, which helps to ensure that a very sharp tip is generated by the milling process.

Continuing with FIG. 1, at block 110 the one or both of the first and second sides of the tip point is/are milled according to the respective milling pattern, thereby creating a reconstructed tip point (generally, a reconstructed tip). For example, tip point 206 is FIB-milled based on the first milling pattern 502 and the second milling pattern 504, to create a reconstructed tip point (see, e.g., tip point 604 of FIG. 6B). In practice, each side likely would be milled one at a time.

FIG. 6A illustrates a microscopic image of a used scanning probe microscopy cantilever tip, according to an embodiment, and FIG. 6B illustrates a microscopic image of a reconstructed used scanning probe microscopy cantilever tip, according to an embodiment. FIGS. 6A, 6B are illustrations of respective microscopic images of a used AFM tip 602 (FIG. 6A), before reconstruction, and a reconstructed tip 604 (FIG. 6B) after being subjected to the FIB milling process referred to in the method described in reference to FIG. 1. As is depicted, portions of the sides of tip 602 have been milled to remove the blunt tip and to create a sharper tip 604.

With reference back to FIG. 1, according to an embodiment, at block 112 the reconstructed tip from block 110 is plasma cleaned, i.e., subjected to plasma cleaning, to create a cleaned reconstructed tip. Plasma cleaning is a feature typical of a FIB instrument. For example, the reconstructed tip may be plasma cleaned for a period of time to remove any contamination and/or deposition that may have been generated as a by-product of the milling process.

Further, according to an embodiment, at block 114, the clean reconstructed tip is exposed to an ionizer. For example, the plasma cleaned reconstructed tip is removed from the FIB instrument and exposed to an ionizer to neutralize the charge on the tip.

As an example, the specification for the tip point height (i.e., the distance between the tip face and the end of the tip point) for a certain manufacturer is 17.5 micrometers. A used tip, prior to reconstruction, was measured to have a tip height of about 14.75 micrometers, due to the blunted tip. Therefore and according to an embodiment, a reconstructed used tip that is subjected to a method for reconstructing a scanning probe microscopy cantilever tip as described or similar to as described in reference to FIG. 1, may be reconstructed to have a tip height less than around 15 micrometers.

To verify the usability of an AFM reconstructed according to the method illustrated in FIG. 1, a reconstructed AFM tip was loaded to the cantilever holder of the AFM tool for testing purposes. A magnetic head slider that was previously analyzed in AFM using the used AFM tip was again analyzed using the reconstructed AFM tip and image and section analysis results were compared. Comparison of the image quality of the magnetic head slider analyzed using three tip conditions showed that the reconstructed AFM tip yielded comparable image quality in comparison with the image of the slider analyzed using a new AFM tip, while the image of the magnetic slider analyzed using the used AFM tip already due for disposal showed a blurred image. Thus, the results showed that the procedure involving reconstruction of a used AFM cantilever tip is feasible because the reconstructed tip yielded results comparable to new tip. Consequently, a manufacturing cost savings associated with the AFM tip consumption rate may be achieved by reconstructing and reusing old tips rather than simply disposing of them upon each instance of a blunted tip and blurred image.

### Extensions and Alternatives

In the foregoing description, embodiments of the invention have been described with reference to numerous specific details that may vary from implementation to implementation. Therefore, various modifications and changes may be made thereto without departing from the broader spirit and scope of the embodiments. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

In addition, in this description certain process steps may be set forth in a particular order, and alphabetic and alphanumeric labels may be used to identify certain steps. Unless specifically stated in the description, embodiments are not necessarily limited to any particular order of carrying out such steps. In particular, the labels are used merely for convenient identification of steps, and are not intended to specify or require a particular order of carrying out such steps.

1. A method for reconstructing a scanning probe microscopy cantilever tip, the method comprising:
mounting a used cantilever coupled with a tip on a focused ion beam (FIB) stub having a cantilever holder, exposing said tip having a tip point;
aligning said cantilever at 0° in the horizontal direction using an xT alignment feature of a FIB instrument using about a 65× magnification view;
aligning said tip point at 90° from the horizontal direction using said xT alignment feature using about a 500× magnification view;
creating a first milling line on a first side and a second milling line on a second side of said tip point using a Line/Polygon feature of said FIB instrument, such that said second milling line intersects with said first milling line on said tip point; and
FIB milling said first side and said second side according to said respective milling lines to create a reconstructed tip.

2. (canceled)

3. (canceled)

4. (canceled)

5. The method of claim 1, further comprising:
plasma cleaning said reconstructed tip to create a cleaned reconstructed tip.

6. The method of claim 5, further comprising:
exposing said cleaned reconstructed tip to an ionizer to neutralize the charge on said cleaned reconstructed tip.

7. (canceled)

8. (canceled)

9. The method of claim 1, wherein mounting a used cantilever coupled with a tip includes mounting a used atomic force microscopy (AFM) cantilever coupled with an AFM tip.

10. A reconstructed used scanning probe microscopy cantilever tip prepared by a process comprising:
mounting a used cantilever coupled with a tip and a tip point on a focused ion beam (FIB) stub having a cantilever holder, exposing said tip;
aligning said cantilever at 0° in the horizontal direction using an xT alignment feature of a FIB instrument using about a 65× magnification view;
aligning said tip point at 90° from the horizontal direction using said xT alignment feature using about a 500× magnification view;
creating a first milling line on a first side and a second milling line on a second side of said tip point using a Line/Polygon feature of said FIB instrument, such that said second milling line intersects with said first milling line on said tip point; and
FIB milling said first side and said second side according to said respective milling lines to create a reconstructed tip.

11. (canceled)

12. (canceled)

13. (canceled)

14. The reconstructed used scanning probe microscopy cantilever tip of claim 10, prepared by a process further comprising:
plasma cleaning said reconstructed tip to create a cleaned reconstructed tip.

15. The reconstructed used scanning probe microscopy cantilever tip of claim 14, prepared by a process further comprising:
exposing said cleaned reconstructed tip to an ionizer to neutralize the charge on said cleaned reconstructed tip.

16. (canceled)

17. (canceled)

18. The reconstructed used scanning probe microscopy cantilever tip of claim 10, wherein said cantilever tip consists of an atomic force microscopy (AFM) cantilever tip.

19. The reconstructed used scanning probe microscopy cantilever tip of claim 10, wherein the height of said cantilever tip point is less than around 15 micrometers.
